(19) United States
(12) Patent Application Publication
(10) Pub. No.: US 2016/0172335 A1
(43) Pub. Date: Jun. 16, 2016

(54) SEMICONDUCTOR DEVICE

(71) Applicant: KABUSHIKI KAISHA TOSHIBA, Tokyo (JP)

(72) Inventor: Nobuyuki SATO, Nonoichi Ishikawa (JP)

(21) Appl. No.: 14/840,849

(22) Filed: Aug. 31, 2015

(30) Foreign Application Priority Data
Dec. 11, 2014 (JP) 2014-251278

(51) Int. Cl. H01L 25/065; H01L 23/367; H01L 25/00

(52) U.S. Cl. CPC H01L 25/0657; H01L 25/50; H01L 23/367; H01L 2225/06513; H01L 2225/06589; H01L 2225/06596

(57) ABSTRACT

A semiconductor device includes a supporting member, a first semiconductor chip on the supporting member and including an overheating detection circuit, a second semiconductor chip on the first semiconductor chip and including a power semiconductor element, and a sealing member on the supporting member, the first semiconductor chip, and the second semiconductor chip. The overheating detection circuit is provided between the second semiconductor chip and the substrate.

### CROSS-REFERENCE TO RELATED APPLICATION

This application is based upon and claims the benefit of priority from Japanese Patent Application No. 2014-251278, filed Dec. 11, 2014, the entire contents of which are incorporated herein by reference.

### FIELD

Embodiments described herein relate generally to semiconductor devices and, in particular, to a semiconductor device provided with a power semiconductor device or element.

### BACKGROUND

In a circuit of a switching power supply, an inverter, and so forth, a power semiconductor device provided with a power semiconductor element such as a switching element and a diode is used. Moreover, a semiconductor device including, in one package, a power semiconductor device and a controller that controls the power semiconductor device is known.

### DESCRIPTION OF THE DRAWINGS

FIG. 1 is a plan view of a semiconductor device according to a first embodiment.

FIG. 2 is a sectional view of the semiconductor device taken on the line A-A′ of FIG. 1.

FIG. 3 is a block diagram of the semiconductor device according to the first embodiment.

FIG. 4 is a plan view of a semiconductor device according to a second embodiment.

FIG. 5 is a sectional view of the semiconductor device taken on the line B-B′ of FIG. 4.

### DETAILED DESCRIPTION

An embodiment provides a semiconductor device that can perform overheating detection with a higher degree of accuracy.

In general, according to one embodiment, a semiconductor device includes: a supporting member; a first semiconductor chip on the supporting member and including an overheating detection circuit; a second semiconductor chip on the first semiconductor chip and including a power semiconductor element; and a sealing member on the supporting member, the first semiconductor chip, and the second semiconductor chip. The overheating detection circuit is provided between the second semiconductor chip and the substrate.

Hereinafter, embodiments will be described with reference to the drawings. It is to be noted that the drawings are schematic or conceptual drawings and the size, the ratio, and so forth of features and elements in each drawing are not always identical to the size, ratio, and so forth of an actual device. Some embodiments which will be described below illustrate a device and a method for embodying a technical concept of an exemplary embodiment, and the shapes, structures, placement, and so forth of the component parts do not limit the technical concept of the exemplary embodiment. Incidentally, in the following description, elements having the same function and configuration will be identified with the same reference characters, and repeated description thereof is given only when necessary.

The following embodiments disclose a semiconductor device housing, in one package, a first semiconductor chip provided with a power semiconductor device including a field-effect transistor and a second semiconductor chip provided with a controller that controls the operation of the power semiconductor device.

### First Embodiment

### [1-1] Configuration of a Semiconductor Device

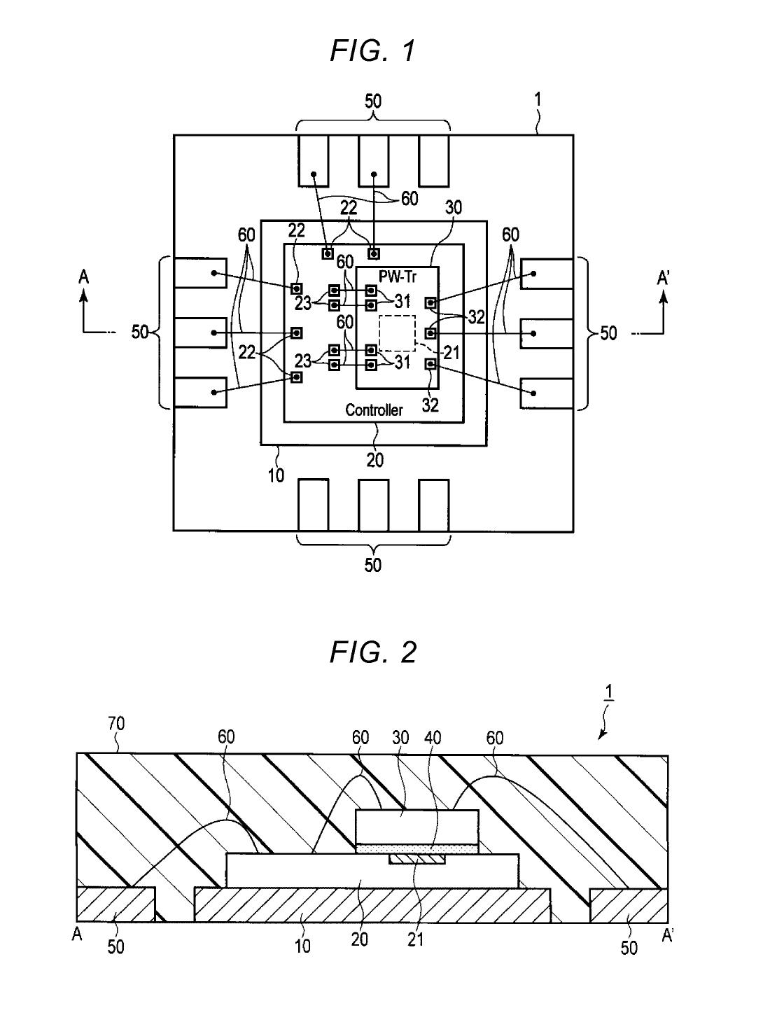

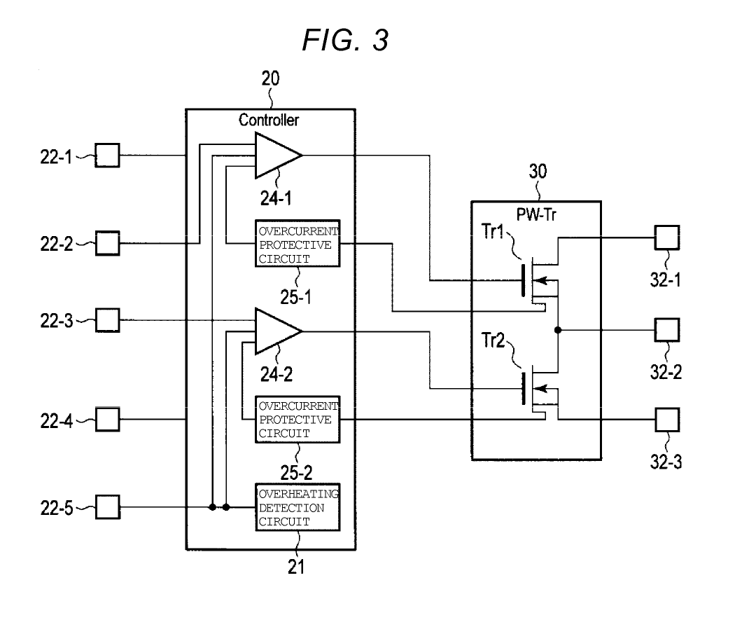

FIG. 1 is a plan view of a semiconductor device 1 according to a first embodiment. FIG. 2 is a sectional view of the semiconductor device 1 taken on the line A-A′ of FIG. 1. The semiconductor device 1 includes a supporting member (a die pad) 10, a semiconductor chip 20, a semiconductor chip 30, a lead terminal group 50, a bonding wire group 60, and a sealing member 70.

The die pad 10 provides a substrate which supports and fixes the location of the semiconductor chips 20 and 30 and also functions as a heat conducting and radiating member. As the die pad 10, a material having high thermal conductivity (for example, metal) is used, for example copper (Cu), an alloy containing copper (Cu), an alloy containing iron (Fe), or the like is used.

The semiconductor chip 20 is provided on the die pad 10 and is fixed to the die pad 10 with an adhesive (not depicted in the drawing). The semiconductor chip 20 is provided with a controller including a microcomputer or the like, and the controller controls the operation of the semiconductor chip 30. The semiconductor chip 20 is provided with an overheating detection circuit 21 and pad groups 22 and 23. The pad groups 22 and 23 are exposed at a top face of the semiconductor chip 20. The pad group 22 is used for electrical connection with the lead terminal group 50, and the pad group 23 is used for electrical connection with the semiconductor chip 30.

The semiconductor chip 30 is provided on the semiconductor chip 20 and is fixed to the semiconductor chip 20 with an adhesive 40. That is, the semiconductor device 1 is a chip-stack type multi-chip package (MCP) formed by stacking the semiconductor chip 30 on the semiconductor chip 20. A bottom surface (a surface opposite to a face on which a pad is formed) of the semiconductor chip 30 is disposed so as to face the top surface (the surface on which a pad is formed) of the semiconductor chip 20. For example, the size of the semiconductor chip 30 is smaller than the size of the semiconductor chip 20.

The semiconductor chip 30 includes a power semiconductor device that performs conversion and control of a power supply (electric power). In general, the power semiconductor device generates a larger amount of heat than a common metal oxide semiconductor field-effect transistor (MOSFET) (for a low voltage). Examples of the power semiconductor device include a power MOSFET, a high electron mobility transistor (HEMT), an insulated-gate bipolar transistor (IGBT), and a diode. The power semiconductor device is formed by using, for example, any one of a nitride semiconductor such as gallium nitride (GaN) and silicon carbide (SiC) or both. In FIG. 1, the semiconductor chip 30 is represented as PW-Tr.

The semiconductor chip 30 includes pad groups 31 and 32. The pad groups 31 and 32 are exposed at a top face of the semiconductor chip 30. The pad group 31 is used for electrical connection with the semiconductor chip 20, and the pad group 32 is used for electrical connection with a portion of the lead terminal group 50.

Here, the overheating detection circuit 21 of the semiconductor chip 20 is disposed in a position closer to the semiconductor chip 30, specifically, below the semiconductor chip 30. Preferably, the whole of the overheating detection circuit 21 is disposed in a region in which the semiconductor chip 20 and the semiconductor chip 30 overlap in a plan view, and therefore the overheating detection circuit 21 is fully covered by the second semiconductor chip 30. Alternatively, only at least part of the overheating detection circuit 21 may be disposed in a region in which the semiconductor chip 20 and the semiconductor chip 30 overlap in a plan view. Moreover, the overheating detection circuit 21 is disposed at or near the top surface of the semiconductor chip 20. The details of the overheating detection circuit 21 will be described later herein.

Preferably, the adhesive 40 bonding together the semiconductor chip 20 and the semiconductor chip 30 is formed of a material having high thermal conductivity. The adhesive 40 is formed by mixing a conductive material into a binder. As the conductive material, metal (metal powder) is used, and, for example, gold (Au), silver (Ag), copper (Cu), or the like is used. As the binder, for example, an organic binder such as an epoxy resin is used. Moreover, as the adhesive 40, silver paste or an epoxy resin may be used.

The lead terminal group 50 is provided around the die pad 10 and is used for electrically connecting the semiconductor chip 20 and the semiconductor chip 30 to an external circuit. As the lead terminal group 50, for example, copper (Cu), an alloy containing copper (Cu), an alloy containing iron (Fe), or the like is used. The lead terminal group 50, together with the die pad 10 described earlier, form a lead frame.

The bonding wire group 60 is used for electrically connecting the semiconductor chip 20 and the lead terminal group 50, electrically connecting the semiconductor chip 30 and the lead terminal group 50, and electrically connecting the semiconductor chip 20 and the semiconductor chip 30. As the material of the bonding wire group 60, for example, gold (Au), copper (Cu), aluminum (Al), or the like is used.

The sealing member 70 seals or encapsulates the die pad 10, the semiconductor chip 20, the semiconductor chip 30, the lead terminal group 50, and the bonding wire group 60. The sealing member 70 is formed of a molding resin or an epoxy resin, for example.

### [1-2] Circuit Configuration of the Semiconductor Device

Next, the circuit configuration of the semiconductor device 1 will be described. FIG. 3 is a block diagram of the semiconductor device 1 according to the first embodiment.

The semiconductor chip (the controller) 20 includes the overheating detection circuit 21, drive circuits (drivers) 24-1 and 24-2, and overcurrent protective circuits 25-1 and 25-2. The semiconductor chip (the power semiconductor device) 30 includes transistors Tr1 and Tr2. The pad group 22 includes pads 22-1 to 22-5. The pad group 32 includes pads 32-1 to 32-3.

In the configuration example of FIG. 3, the transistors Tr1 and Tr2 are switching elements which are used in a half-bridge circuit. Each of the transistors Tr1 and Tr2 is formed of a high-voltage N-channel MOSFET (power MOSFET), for example. In FIG. 3, as the transistors Tr1 and Tr2, N-channel MOSFETs are depicted. Incidentally, the number of the power semiconductor elements of the semiconductor chip 30 and the type of the power semiconductor elements can be designed arbitrarily.

The drain of the transistor Tr1 is electrically connected to the pad 32-1, and the source of the transistor Tr1 is electrically connected to the pad 32-2. The gate of the transistor Tr1 is electrically connected to the output of the drive circuit 24-1. Moreover, the source of the transistor Tr1 is electrically connected to the input of the overcurrent protective circuit 25-1.

The drain of the transistor Tr2 is electrically connected to the pad 32-2, and the source of the transistor Tr2 is electrically connected to the pad 32-3. The gate of the transistor Tr2 is electrically connected to the output of the drive circuit 24-2. Moreover, the source of the transistor Tr2 is electrically connected to the input of the overcurrent protective circuit 25-2.

The overheating detection circuit 21 detects the temperature of the semiconductor chip 30 and determines whether or not the temperature of the semiconductor chip 30 exceeds a threshold temperature. Specifically, the overheating detection circuit 21 detects the temperature thereof caused by transfer of the heat generated by the semiconductor chip 30 to the overheating detection circuit 21. The threshold temperature of the overheating detection circuit 21 is appropriately set in accordance with the specifications of the semiconductor chip 30. The overheating detection circuit 21 supplies an overheating detection signal to the drive circuits 24-1 and 24-2. Moreover, the output of the overheating detection circuit 21 is electrically connected to the pad 22-5. For example, the overheating detection circuit 21 causes the overheating detection signal to transition from a low level to a high level if the temperature of the semiconductor chip 30 exceeds a threshold value.

The overheating detection circuit 21 includes an element having characteristics which change based on the temperature thereof. Examples of the element having temperature characteristics include a diode and a resistance element. If a diode (a pn junction diode) is used in the overheating detection circuit 21, when a constant current is passed through the diode, the forward voltage VF value varies depending on the ambient temperature of the diode. Therefore, by comparing the forward voltage VF of the diode with a reference voltage, the overheating detection circuit 21 can perform overheating detection.

The overcurrent protective circuit 25-1 detects the current flowing through the transistor Tr1 and determines whether or not the current flowing through the transistor Tr1 exceeds a threshold current. The threshold current of the overcurrent protective circuit 25-1 is appropriately set depending on the specification for the semiconductor chip 30. The overcurrent protective circuit 25-1 supplies an overcurrent detection signal to the drive circuit 24-1 when an overcurrent condition occurs. For example, the overcurrent protective circuit 25-1 makes the overcurrent detection signal transition from a low level to a high level if the current flowing through the transistor Tr1 exceeds the threshold current. The overcurrent protective circuit 25-2 performs overcurrent protection of the transistor Tr2. The configuration of the overcurrent protective circuit 25-2 is the same as the configuration of the overcurrent protective circuit 25-1.

The drive circuit 24-1 is electrically connected to the pad 22-2. Moreover, the drive circuit 24-1 receives the overheating detection signal from the overheating detection circuit 21 and receives the overcurrent detection signal from the overcurrent protective circuit 25-1. The drive circuit 24-1 controls ON/OFF of the transistor Tr1 by controlling the gate voltage of the transistor Tr1 based on the control signal input to the pad 22-2. Moreover, the drive circuit 24-1 turns off the transistor Tr1 if any one of the overheating detection signal, the overcurrent detection signal, or both occur.

The drive circuit 24-2 is electrically connected to the pad 22-3, the overheating detection circuit 21, and the overcurrent protective circuit 25-2. The drive circuit 24-2 drives the transistor Tr2. The configuration of the drive circuit 24-2 is the same as the configuration of the drive circuit 24-1.

### [1-3] Operation

Next, the operation of the semiconductor device 1 configured as described above will be described.

If a control signal is input to the pad 22-2, the drive circuit 24-1 turns on the transistor Tr1; if the control signal input to the pad 22-2 is negated, the drive circuit 24-1 turns off the transistor Tr1. Likewise, if a control signal is input to the pad 22-3, the drive circuit 24-2 turns on the transistor Tr2; if the control signal input to the pad 22-3 is negated, the drive circuit 24-2 turns off the transistor Tr2. By such an operation, the semiconductor device 1 can perform control of the power supply supplied to the semiconductor device 1, for example.

While the semiconductor device 1 is operating, the semiconductor chip 30 generates heat and the temperature of the semiconductor chip 30 rises. The overheating detection circuit 21 detects the temperature of the semiconductor chip 30. If the temperature of the semiconductor chip 30 exceeds a threshold temperature, the overheating detection circuit 21 sends out an overheating detection signal. When receiving the overheating detection signal, the drive circuits 24-1 and 24-2 turn off the transistors Tr1 and Tr2, respectively. In this way, the overheating detection circuit 21 can suppress a breakdown or degradation of the semiconductor chip 30 caused by heat.

Here, as depicted in FIGS. 1 and 2, the overheating detection circuit 21 is disposed below the semiconductor chip 30. Thus, the overheating detection circuit 21 can detect the temperature of the semiconductor chip 30 with a higher degree of accuracy. As a result, the overheating detection circuit 21 can perform the overheating detection operation with a higher degree of accuracy.

On the other hand, if the temperature of the semiconductor chip 30 falls below the threshold temperature, the overheating detection circuit 21 negates the overheating detection signal. When receiving the negated overheating detection signal, the drive circuits 24-1 and 24-2 control ON/OFF of the transistors Tr1 and Tr2, respectively, in accordance with the control signal sent from the pad 22-1 and 22-3.

Moreover, the overcurrent protective circuit 25-1 detects the current flowing through the transistor Tr1. If the current flowing through the transistor Tr1 exceeds the threshold current, the overcurrent protective circuit 25-1 sends the overcurrent detection signal. When receiving the asserted overcurrent detection signal, the drive circuit 24-1 turns off the transistor Tr1. The operation of the overcurrent protective circuit 25-2 is the same as the operation of the overcurrent protective circuit 25-1. In this way, the overcurrent protective circuits 25-1 and 25-2 can suppress a breakdown or degradation of the semiconductor chip 30 caused by the overcurrent.

### [1-4] Effect of the First Embodiment

The power semiconductor device that performs switching or rectification of a power supply generates a large amount of heat during the operation. If the temperature of the power semiconductor device rises, the possibility of degradation of a semiconductor layer or occurrence of a dielectric breakdown is increased, which leads to breakdown or degradation of the power semiconductor device due to overheating. Thus, in the semiconductor device provided with the power semiconductor device, the controller controlling the power semiconductor device includes the overheating detection circuit, and the controller performs detection of overheating of the power semiconductor device. As the semiconductor device having the overheating detecting function, for example, a plane-type MCP in which the power semiconductor device and the controller are disposed side by side in planar implementation and are thus packaged is used.

However, the size of the plane-type MCP is large and becoming larger, and thus the wiring between the chips is increased in length. The semiconductor device using the plane-type MCP has a high parasitic inductance and therefore the operation frequency thereof cannot be increased. Moreover, if the power semiconductor device and the controller provided with the overheating detection circuit are packaged in a planar side by side implementation, the distance between the power semiconductor device and the overheating detection circuit is undesirably increased, resulting in less accuracy of an over-temperature condition. Since the accuracy of the detection of the temperature of the power semiconductor device in the overheating detection circuit is decreased, there is a possibility that the semiconductor device cannot prevent a thermal failure thereof by switching of when in an over-temperature condition.

Thus, in the semiconductor device 1 according to the first embodiment, the semiconductor chip (the power semiconductor device) 30 is disposed on the semiconductor chip (the controller) 20 provided with the overheating detection circuit 21. Moreover, the overheating detection circuit 21 is disposed below the semiconductor chip 30. Thus, the distance between the semiconductor chip 30 and the overheating detection circuit 21 is reduced. As a result, the overheating detection circuit 21 can detect the temperature of the semiconductor chip 30 with a higher degree of accuracy, and the implementation of the semiconductor device 1 that can perform the overheating/over-temperature detecting function of the semiconductor chip 20 with a higher degree of accuracy is possible. As a result, suppression of a breakdown or degradation of the semiconductor device 1 caused by heat is possible.

Moreover, the semiconductor device 1 is formed of the chip-stack type MCP in which the semiconductor chip 30 is stacked on the semiconductor chip 20. As a result, the size of the semiconductor device 1 may be reduced.

Furthermore, the bonding wire group 60 connecting the semiconductor chip 20 and the semiconductor chip 30 can be shortened in length. As a result, the inductance of the wiring can be lowered, and higher-frequency operation can be achieved.

In the first embodiment, two semiconductor chips are stacked. However, the embodiment is not limited thereto, and a chip-stack type MCP may be formed by stacking three or more semiconductor chips one over the other. In this case, by disposing the overheating detection circuit 21 below the semiconductor chip provided with the power semiconductor device, the above-described effect can be obtained.

### Second Embodiment

In a second embodiment, a semiconductor device 1 is formed by connecting together a semiconductor chip (a controller) 20 and a semiconductor chip (a power semiconductor device) 30 using the flip-chip packaging technique. Furthermore, by providing a heat removing member (a heat sink) 11 on the semiconductor chip 30, the heat removal efficiency of the semiconductor chip 30 is increased.

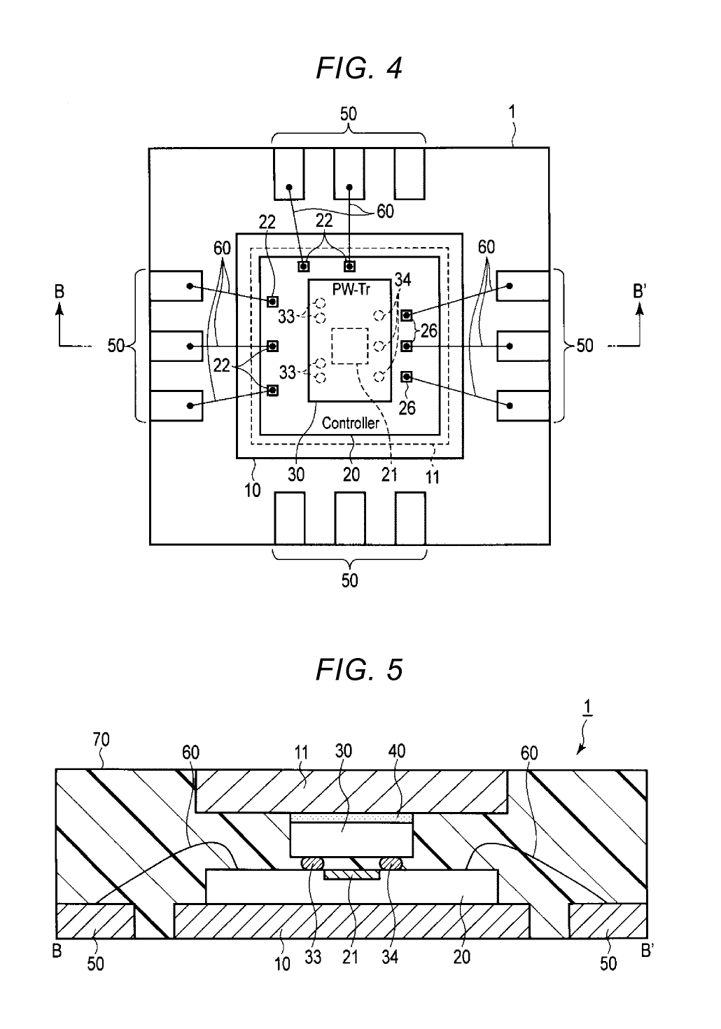

FIG. 4 is a plan view of the semiconductor device 1 according to the second embodiment. FIG. 5 is a sectional view of the semiconductor device 1 taken on the line B-B′ of FIG. 4. The semiconductor device 1 includes the heat sink 11.

The semiconductor chip 30 is mounted on the semiconductor chip 20 in a flip-chip configuration with conductive bump groups 33 and 34 interposed therebetween. That is, the semiconductor chip 20 and the semiconductor chip 30 are electrically connected to each other with the bump groups 33 and 34 interposed therebetween in such a way that a top surface (a surface on which a pad is formed) of the semiconductor chip 20 and a top surface (a surface on which a pad is formed) of the semiconductor chip 30 face each other. As the material of the bump groups 33 and 34, gold (Au), silver (Ag), tin (Sn), an alloy containing any one of gold (Au), silver (Ag), and tin (Sn), or the like may be used.

The bump group 33 is electrically connected to a pad group 31 (not depicted in the drawing) of the semiconductor chip 30 and is electrically connected to a pad group 23 (not depicted in the drawing) of the semiconductor chip 20. The bump group 34 is electrically connected to a pad group 32 (not depicted in the drawing) of the semiconductor chip 30 and is electrically connected to a pad group 26 of the semiconductor chip 20 via wiring (not depicted in the drawing). The pad group 26 of the semiconductor chip 20 is electrically connected to a lead terminal group 50 via a bonding wire group 60.

On a bottom face of the semiconductor chip 30, the heat sink 11 is provided with an adhesive 40 interposed between the bottom face of the semiconductor chip 30 and the heat sink 11. The heat sink 11 has the function of removing the heat generated by the semiconductor chip 30. As the heat sink 11, a material having high thermal conductivity (metal) is used, and copper (Cu), an alloy containing copper (Cu), an alloy containing iron (Fe), or the like is used. The heat sink 11 has substantially the same size as the die pad 10, for example. The adhesive 40 is formed of the same material as the adhesive described in the first embodiment.

A sealing member 70 seals (encapsulates) the die pad 10, the heat sink 11, the semiconductor chip 20, the semiconductor chip 30, the bump groups 33 and 34, the lead terminal group 50, and the bonding wire group 60.

As detailed above, in the second embodiment, the semiconductor chip 20 and the semiconductor chip 30 are mounted in a flip-chip configuration and the heat sink 11 is provided on the bottom surface of the semiconductor chip 30 with the adhesive 40 interposed between the bottom face of the semiconductor chip 30 and the heat sink 11. This structure can improve the heat removal (conduction and radiation) efficiency of the semiconductor device 1. As a result, a breakdown or degradation of the semiconductor device 1 caused by heat may be reduced.

Moreover, use of the flip-chip mounting can reduce the number of bonding wires 60 as compared to the number of bonding wires 60 needed in the first embodiment. As a result, the parasitic inductance can be lowered as compared to the parasitic inductance in the first embodiment, and the implementation of the semiconductor device 1 that can perform higher-frequency operation can be achieved.

Furthermore, as in the first embodiment, the overheating detection circuit 21 is disposed directly below the semiconductor chip 30. As a result, the overheating detection circuit 21 can detect the temperature of the semiconductor chip 30 with a higher degree of accuracy, and the implementation of a semiconductor device 1 that can perform the overheating detection of the semiconductor chip 20 with high accuracy can be achieved.

In the present specification, “stacking” includes, in addition to a case in which layers are stacked in such a way as to make contact with each other, a case in which layers are stacked with another layer inserted between the layers. Moreover, “providing a layer on something” includes, in addition to a case in which layers are provided in such a way as to make contact with each other, a case in which layers are provided with another layer inserted between the layers.

The exemplary embodiment is not limited to the embodiments described above and can be embodied by modifying the component element within the spirit of the embodiments. Furthermore, the embodiments described above include embodiments at various stages, and various embodiments can be configured with an appropriate combination of a plurality of component elements disclosed in one embodiment or an appropriate combination of the component elements disclosed in different embodiments. For example, if the problem to be solved by the exemplary embodiment can be solved and the effect of the exemplary embodiment can be obtained even when some of the component elements are deleted from all the component elements disclosed in the embodiments, an embodiment obtained after the deletion of these component elements can be extracted as an embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a supporting member;
a first semiconductor chip on the supporting member and including an overheating detection circuit;
a second semiconductor chip on the first semiconductor chip and including a power semiconductor element; and
a sealing member on the supporting member, the first semiconductor chip, and the second semiconductor chip,
wherein
the overheating detection circuit is between the supporting member and the second semiconductor chip.

2. The semiconductor device according to claim 1, wherein
a first surface of the second semiconductor chip has at least one pad thereon, and
a second surface of the second semiconductor chip opposite to a first surface of the second semiconductor chip on which a pad is formed is disposed so as to face a first surface of the first semiconductor chip.

3. The semiconductor device according to claim 2, further comprising:
an adhesive extending between the first semiconductor chip and the second semiconductor chip,
wherein the adhesive contains a metal.

4. The semiconductor device according to claim 1, wherein the first semiconductor chip and the second semiconductor chip are electrically connected by a plurality of bumps.

5. The semiconductor device according to claim 4, further comprising:
a heat removing member provided on the second semiconductor chip.

6. The semiconductor device according to claim 5, further comprising:
an adhesive extending between the second semiconductor chip and the heat radiating member,
wherein the adhesive contains a metal.

7. The semiconductor device according to claim 1, wherein the overheating detection circuit is provided on a surface of the first semiconductor chip facing the second semiconductor chip.

8. A method of protecting a semiconductor device from overheating, wherein the semiconductor device includes at least a first chip of a first type and a second chip of a second type, the second chip of the second type generating more heat than the first chip of the first type during operation of the semiconductor device, the method comprising:
providing a heat detection element on the first chip;
locating the first chip on a substrate such that the heat detection element is located at a surface of the first chip not facing the substrate; and
providing the second chip over a surface of the first chip at which the heat detection element is located.

9. The method of claim 8, further comprising providing an adhesive between the first chip and the second chip.

10. The method of claim 8, further comprising:
providing at least one pad on the surface of the first chip at which the heat detection element is located;
providing at least one pad on a surface of the second chip; and
electrically connecting the pad on the first chip to the pad on the second chip.

11. The method of claim 10, further comprising providing a wire connection between the pad on the first chip and the pad on the second chip.

12. The method of claim 10, further comprising:
positioning the pad on a surface of the second chip in a facing relationship with the pad on the surface of the first chip; and
electrically connecting the pad on the first chip to the pad on the second chip.

13. The method of claim 8, wherein the surface of the first chip at which the heat detection element is formed is opposed to the surface of the first chip facing the substrate.

14. The method of claim 8, wherein the second chip comprises a power semiconductor device.

15. The method of claim 8, wherein the substrate comprises a metal heat sink.

16. A semiconductor device comprising:
at least a first chip of a first type and a second chip of a second type, the second chip of the second type generating more heat than the first chip of the first type during operation of the semiconductor device;
a substrate on which the first chip is mounted; and
a temperature detecting element disposed in the first chip,
wherein the second chip is located against a surface of the first chip in a location to overlie the location of the temperature detection element in the first chip.

17. The semiconductor device of claim 16, wherein the second chip overlies a portion of the temperature detection element.

18. The semiconductor device of claim 16, wherein the second chip is electrically connected to the first chip.

19. The semiconductor device of claim 18, wherein the second chip is electrically connected to the substrate.

20. The semiconductor device of claim 18, wherein the first chip is electrically connected to the substrate.
